(19) United States
(12) Patent Application Publication
(10) Pub. No.: US 2022/0181443 A1
(43) Pub. Date: Jun. 9, 2022

(54) Power MOSFET With Enhanced Cell Design

(71) Applicants: Xiaotian Yu, LOS ANGELES, CA (US); Zheng Zuo, LOS ANGELES, CA (US); Ruigang Li, LOS ANGELES, CA (US)

(72) Inventors: Xiaotian Yu, LOS ANGELES, CA (US); Zheng Zuo, LOS ANGELES, CA (US); Ruigang Li, LOS ANGELES, CA (US)

(73) Assignee: AZ Power, Inc, CULVER CITY, CA (US)

(21) Appl. No.: 17/545,838

(22) Filed: Dec. 8, 2021

Related U.S. Application Data
(60) Provisional application No. 63/122,784, filed on Dec. 8, 2020.

(51) Int. Cl. H01L 29/10; H01L 29/16; H01L 29/66

(52) U.S. Cl. CPC H01L 29/1066; H01L 29/66068; H01L 29/1608

(57) ABSTRACT

A semiconductor device comprising a substrate having a first conductivity type; an epitaxial layer having the first conductivity type deposited on the substrate; and a MOS structure formed on the epitaxial layer; said MOS structure including multiple well regions with a second conductivity type; multiple source regions with highly doped first conductivity type formed in the well regions; multiple highly doped regions of the second conductivity type formed in the well regions; an insulating gate oxide layer formed on top of the epitaxial layer and spanned adjacent wells and source regions; and a gate electrode formed above the gate oxide layer and spanned adjacent wells and source regions, wherein a JFET region is formed between two adjacent wells; and one or more central implant regions are added with the second conductivity type on a surface of the JFET region to reduce an electric field in the gate oxide.

### CROSS-REFERENCE TO RELATED APPLICATIONS

This application claims priority under 35 U.S.C. § 119 (e) to U.S. Provisional Patent Application Ser. No. 63/122,784, filed on Dec. 8, 2020, the entire contents of which are hereby incorporated by reference.

### FIELD OF THE INVENTION

Power devices may include power diodes and power transistors. Power MOSFET is one of the power transistors, which is widely used in the power supply. Under operation conditions, power MOSFET devices need the capability to withstand high voltage and high current.

The present invention is related to a power MOSFET structure, which is a double-implanted MOSFET (DIMOSFET), which improves the device reliability of the power MOSFET under the forward blocking mode.

### BACKGROUND OF THE INVENTION

Silicon carbide (SiC) semiconductor has two times larger bandgap compared to Silicon semiconductor. With higher critical electric field, higher thermal conductivity, lower intrinsic carrier concentration and higher saturation drift velocity, silicon carbide semiconductor has become an ideal candidate for high voltage, high temperature and high-power devices.

SiC power MOSFET can achieve fast switching speed and low on-resistance. In addition, it can attain a higher breakdown voltage through a thinner epitaxial layer (drift layer) thickness, reducing the volume and energy consumption of the power switch module. Based on the above features, SiC power MOSFET has obvious advantages in power systems.

There are two technical routes for commercial SiC MOSFET devices, namely planar power MOSFET and trench-gate power MOSFET. Among them, planar power MOSFET devices are favored by commercial devices due to relatively simple process flow.

### SUMMARY OF THE INVENTION

In one aspect, a planar SiC power MOSFET device may include a substrate having a first conductivity type; an epitaxial layer having the first conductivity type deposited on one side of the substrate; and a MOS (metal-oxide-semiconductor) structure formed on the epitaxial layer. In one embodiment, the MOS structure may include a plurality of well regions with a second conductivity type which is different from the first conductivity type, and the well region and the epitaxial layer form a PN junction; a plurality of source regions with highly doped first conductivity type formed in the well regions on the epitaxial layer, and the source region forms another PN junction with the well region; a plurality of highly doped regions of the second conductivity type formed in the well region on the epitaxial layer; an insulating gate oxide layer formed on top of the epitaxial layer and spanned adjacent wells and adjacent source regions; and a gate electrode formed above the gate oxide layer and spanned adjacent wells and source regions, wherein a JFET (junction-gate filed-effect transistor) region is formed between two adjacent wells; and one or more central implant regions are added with the second conductivity type on a surface of the JFET region to reduce an electric field in the gate oxide.

In one embodiment, a source electrode is formed on top of the planar SiC power MOSFET device, and the gate electrode and the source electrode are separated by an insulating dielectric layer; and a drain electrode is formed on the other side of the substrate.

In another embodiment, the central implant region can be rectangular, circular, hexagonal, octagonal or any other polygonal shapes.

In a further embodiment, the central implant regions can be connected with each other, and then connected to the source region.

### BRIEF DESCRIPTION OF THE DRAWINGS

FIG. 1 is a cross-section schematic view of a traditional planar power MOSFET.

FIG. 2 is an E-field distribution in traditional planar SiC power MOSFET devices under forward blocking mode.

FIG. 3 is a partial layout design of a conventional planar power MOSFET with a strip cell design in the prior art.

FIG. 4 is a partial layout design of a planar power MOSFET with an enhanced strip cell design A.

FIG. 5 is a partial layout design of a planar power MOSFET with the enhanced hexagonal cell design A.

FIG. 6 is a partial layout design of a planar power MOSFET with the enhanced octagonal cell design A.

FIG. 7 is a partial layout design of a planar power MOSFET with an enhanced hexagonal cell design B.

FIG. 8 is a partial layout design of a planar power MOSFET with the enhanced octagonal cell design B.

FIG. 9 is a partial layout design of a planar power MOSFET with an enhanced hexagonal cell design C.

FIG. 10 is a partial layout design of a planar power MOSFET with an enhanced circular cell design D.

FIG. 11 is a partial layout design of a planar power MOSFET with the enhanced octagonal cell design D.

FIG. 12 is a partial layout design of a planar power MOSFET with the enhanced hexagonal cell design D.

FIG. 13 is a partial layout design of a planar power MOSFET with the enhanced square cell design D.

### DETAILED DESCRIPTION OF THE INVENTION

The detailed description set forth below is intended as a description of the presently exemplary device provided in accordance with aspects of the present invention and is not intended to represent the only forms in which the present invention may be prepared or utilized. It is to be understood, rather, that the same or equivalent functions and components may be accomplished by different embodiments that are also intended to be encompassed within the spirit and scope of the invention.

Unless defined otherwise, all technical and scientific terms used herein have the same meaning as commonly understood to one of ordinary skill in the art to which this invention belongs. Although any methods, devices and materials similar or equivalent to those described can be used in the practice or testing of the invention, the exemplary methods, devices and materials are now described.

All publications mentioned are incorporated by reference for the purpose of describing and disclosing, for example, the designs and methodologies that are described in the publications that might be used in connection with the presently described invention. The publications listed or discussed above, below and throughout the text are provided solely for their disclosure prior to the filing date of the present application. Nothing herein is to be construed as an admission that the inventors are not entitled to antedate such disclosure by virtue of prior invention.

As used in the description herein and throughout the claims that follow, the meaning of “a”, “an”, and “the” includes reference to the plural unless the context clearly dictates otherwise. Also, as used in the description herein and throughout the claims that follow, the terms “comprise or comprising”, “include or including”, “have or having”, “contain or containing” and the like are to be understood to be open-ended, i.e., to mean including but not limited to. As used in the description herein and throughout the claims that follow, the meaning of “in” includes “in” and “on” unless the context clearly dictates otherwise.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the embodiments. As used herein, the term “and/or” includes any and all combinations of one or more of the associated listed items.

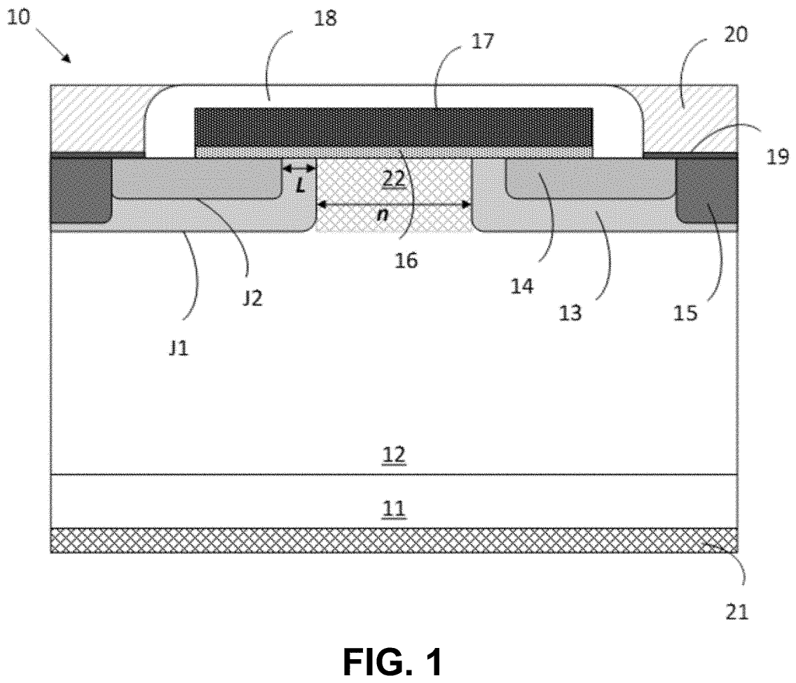

In one aspect as shown in FIG. 1 for a cross-section schematic of a conventional planar SiC power MOSFET device (device 10), including a silicon carbide substrate having a first conductivity type (FIG. 1 structure 11). The epitaxial layer (FIG. 1 structure 12) with a first conductivity type is formed on the substrate, and it has doping concentration lower than the substrate. A MOS structure is formed on the surface of the epitaxial layer, which includes:

(1) Multiple well regions with second conductivity type which is different from the first conductivity type (FIG. 1 structure 13). And the well region and the epitaxial layer form the PN junction (FIG. 1 structure J1). The region between the adjacent well regions is regarded as JFET region (FIG. 1 structure 22);

(2) Multiple source regions with highly doped first conductivity type (FIG. 1 structure 14) are formed in the well regions on the surface of the epitaxial layer. And source region forms another PN junction with the well region (FIG. 1 structure J2);

(3) Multiple highly doped regions of the second conductivity type (FIG. 1 structure 15) are formed in the well region on the surface of the epitaxial layer. In order to suppress the parasitic bipolar transistor inside the MOSFET device, the source metal (FIG. 1 structure 19) is in contact with the source region (FIG. 1 structure 14) and highly doped region (FIG. 1 structure 15) at the same time;

(4) The insulating gate oxide layer (FIG. 1 structure 16) is formed on top of the epitaxial layer and spans the adjacent well (FIG. 1 structure 13) and source regions (FIG. 1 structure 14); and

(5) The gate electrode (FIG. 1 structure 17) is formed above the gate oxide layer and also spans the adjacent well (FIG. 1 structure 13) and source region (FIG. 1 structure 14).

The source electrode (FIG. 1 structure 20) is formed on top of the device. The gate electrode (FIG. 1 structure 17) and the source electrode (FIG. 1 structure 20) are separated by an insulating dielectric layer (FIG. 1 structure 18). A drain electrode (FIG. 1 structure 21) is formed on the back side of the substrate (FIG. 1 structure 11).

Under the forward blocking mode, a high bias voltage (close to the maximum operating voltage) is applied to the drain and the gate is maintained under operating conditions near ground potential. According to Gauss's law, the electric field in the gate oxide layer above the JFET region has the following relationship with the electric field in the semiconductor:

E_{oxide}=(ε_{Semi}/ε_{Oxide})E_{Semi}

Here, ε_{Semi} and ε_{Oxide} are the dielectric constants of the silicon carbide and the gate oxide layer, respectively, and Eₛₑₘᵢ is the electric field in the semiconductor under the gate oxide layer. For silicon carbide, the critical E-field is about 3×10⁶ V/cm. When the semiconductor in the MOSFET device reaches this value, the E-field in the gate oxide layer has already exceeded the safety threshold for long-term operation of the device, which is 4×10⁶ V/cm.

In the long-term blocking mode, the drain is placed under a high positive bias, and defects in the gate oxide may eventually cause the device to fail. Also, when the drain is placed a high positive bias, in traditional MOSFET devices, hot carrier injection may also occur at the interface between SiC and the gate oxide layer in the long-term blocking mode.

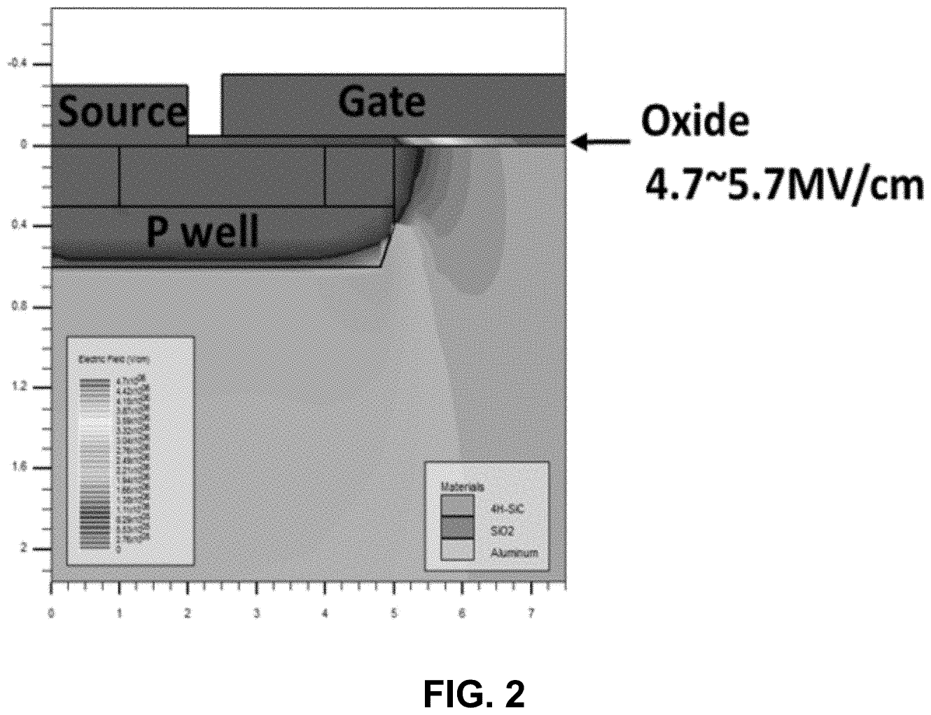

FIG. 2 is a simulation of E-field distribution in traditional planar SiC power MOSFET device under forward blocking mode. It is obvious that a high electric field is located in the gate oxide directly above the JFET area. It is important to note that the present invention is based on the design of the power MOSFET device structure. Through the electric field shielding structure within the cell design, the electric field in the gate oxide can be reduced without changing the process flow and cost and without sacrificing many other properties.

In the active area of the power MOSFET device, the portion where conduct the operating current is formed by a uniform arrangement of multiple repeating cells. The cell shape of the planar power MOSFET device can be a strip, circle, or polygon. Under the same area, compared to striped cell design, s the device area can be used more efficiently with circular and polygonal cell design to achieve a smaller specific on-resistance and reduce the conduction loss of MOSFET devices.

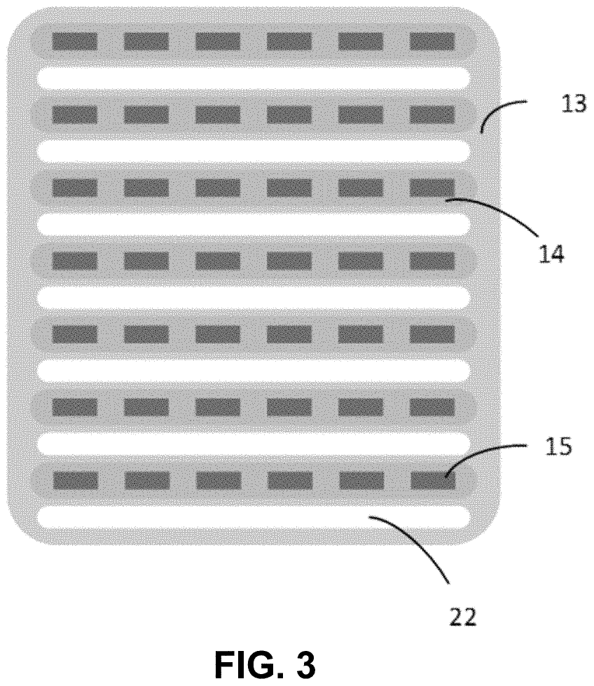

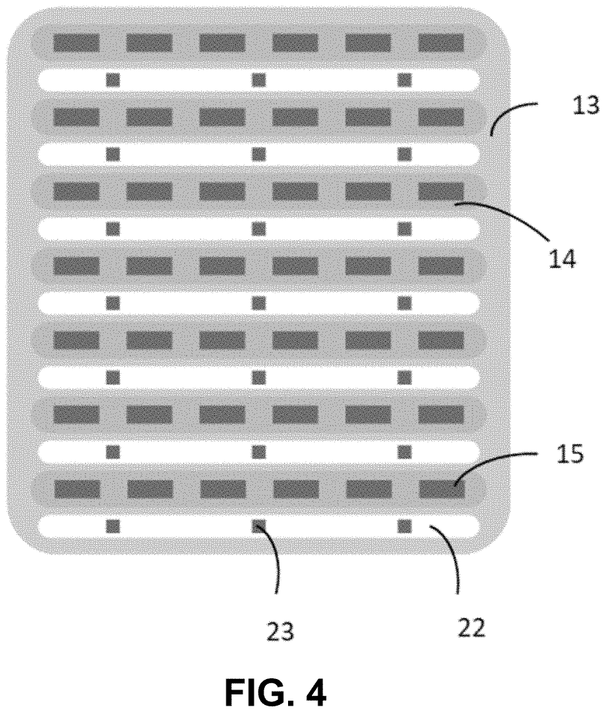

FIG. 3 shows the partial layout design of a conventional planar power MOSFET with a strip cell design, and the structure 22 is the JFET region mentioned before. Based on the design shown in FIG. 3, to reduce the electric field in the gate oxide, one or more doped regions will be added with the second conductivity type on the surface of the JFET region, which are named the central implant (FIG. 4 structure 23). FIG. 4 shows an enhanced strip cell design, the structure of the central implants can play a role in shielding the electric field, thereby reducing the electric field in the gate oxide layer.

However, the design shown in FIG. 4 will sacrifice part of the JFET area that used to conduct current, thereby increasing the on-resistance of the device. In order to solve this problem, the present invention takes an advantage of the higher area utilization of the circular and polygonal cell design (under the same area, circular and polygonal cell designs are more efficient), and proposes a planar power MOSFET with enhanced circular and polygonal cell designs, which reduces the E-field in the gate oxide through the reasonable shielding structure design without changing the process flow and cost, and without sacrificing any other performance. As a result, the reliability of the power MOSFET can be improved.

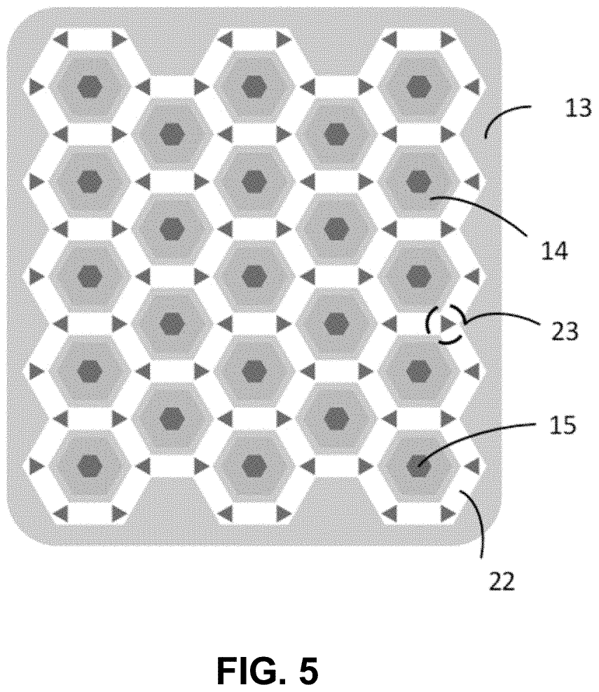

FIG. 5 is a partial layout design of a planar MOS device with an enhanced hexagonal cell design. Similar to the enhanced strip cell design, central implants (FIG. 5 structure 23) are added to the JFET area (FIG. 5 structure 22), which can help shield the electric field under the forward blocking mode to reduce the E-field in the gate oxide.

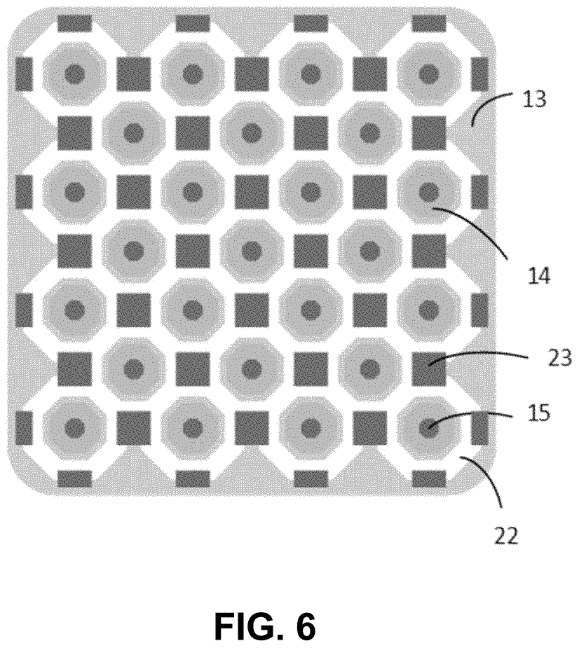

Similarly, we can get the enhanced octagonal cell design shown in FIG. 6. It is important to note here that the central implants can be any shape (such as a circle, a polygon, etc.). Furthermore, the central implants design shown in FIGS. 4 to 6 is also applicable to circular, polygonal cells, etc. For the convenience of explanation, only strip (rectangular), hexagonal and octagonal cells are illustrated in this invention.

It should be noted here that in order not to affect the conduction performance of the device, the central implant structures shown in FIGS. 4 to 6 need to be connected to the source. However, in the real device manufacturing, the design shown in FIGS. 4 to 6 have higher requirements for process capabilities (the size of the central implant structure is limited by the minimum line width of the ohmic contact, etc.). To further solve this problem, the structure design with higher feasibility will be discussed as follows.

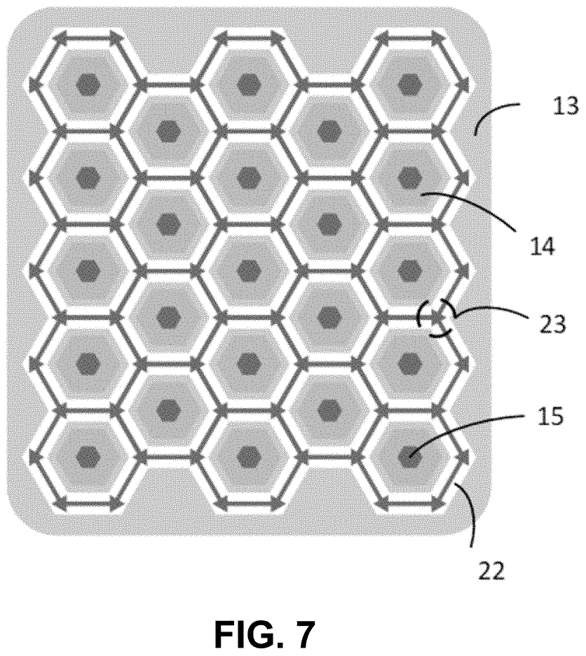

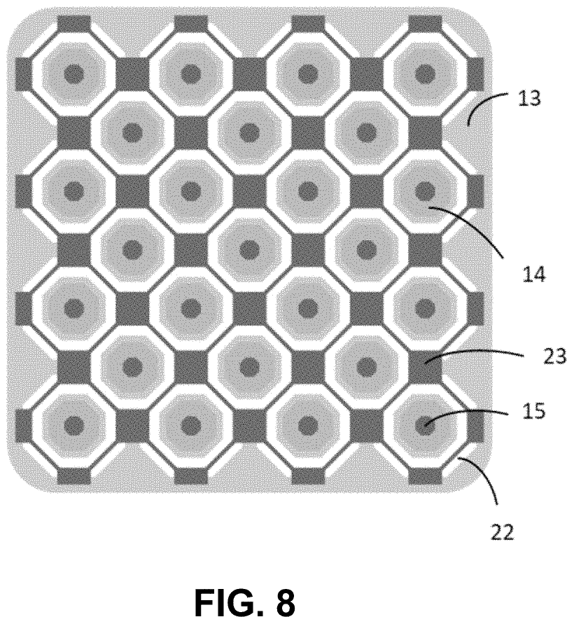

The network central implant structure in FIG. 7 and FIG. 8 can connect the isolated P+ central implants in FIG. 5 and FIG. 6, and then connect to the source in the transition area of the device. Based on the design, the active area of the MOSFET can maintain a small central implant size without sacrificing too much conduction performance of the device.

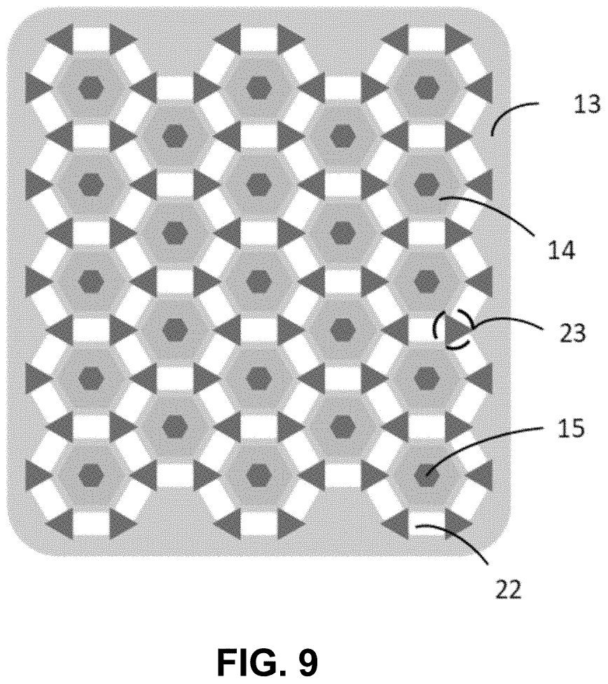

More importantly, the size of the central implant can be adjusted. As shown in FIG. 9, the central implant can expand and connect to the well region to connect to the source. Besides the highly doped central implant structure, the well regions can also play the role of electric field shielding. Therefore, it is also applicable to replace the central implants in FIGS. 7 to 9 with the well regions.

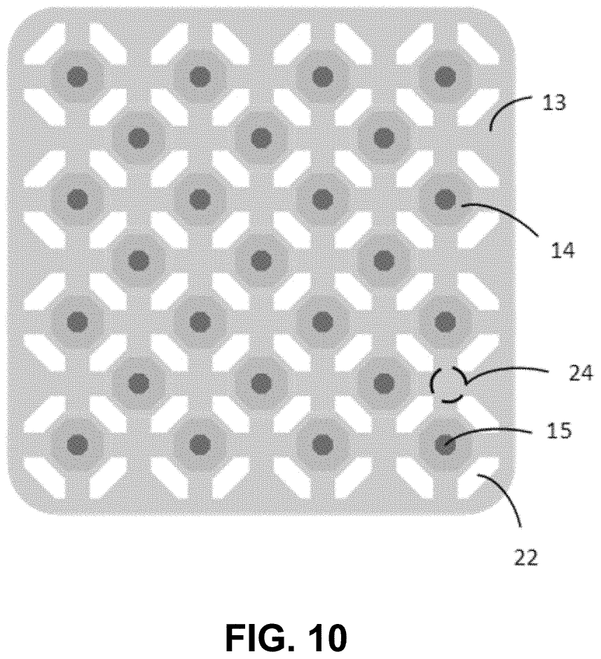

In another embodiment, as shown in FIG. 10, it is a partial layout design of a planar MOSFET with an enhanced octagonal cell design D. The JFET regions (FIG. 10 structure 22) becomes independent from each other. And the well regions (FIG. 10 structure 24) between adjacent JFET regions can help reduce the E-field in the gate oxide under the forward blocking mode.

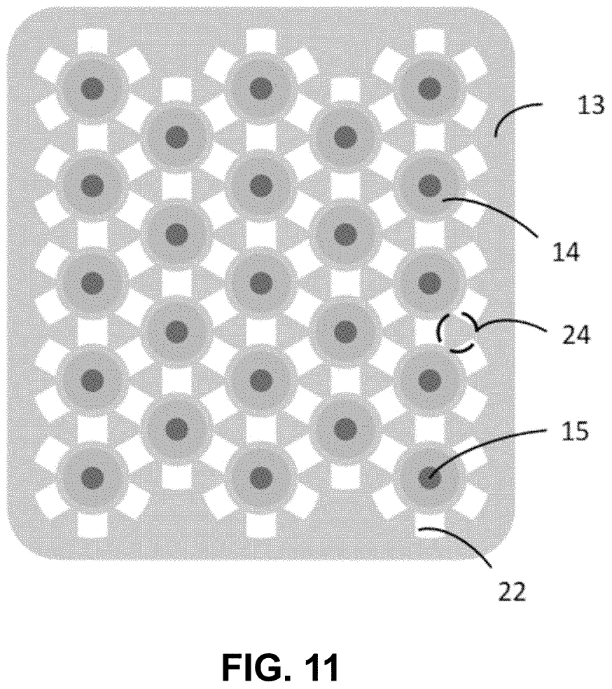

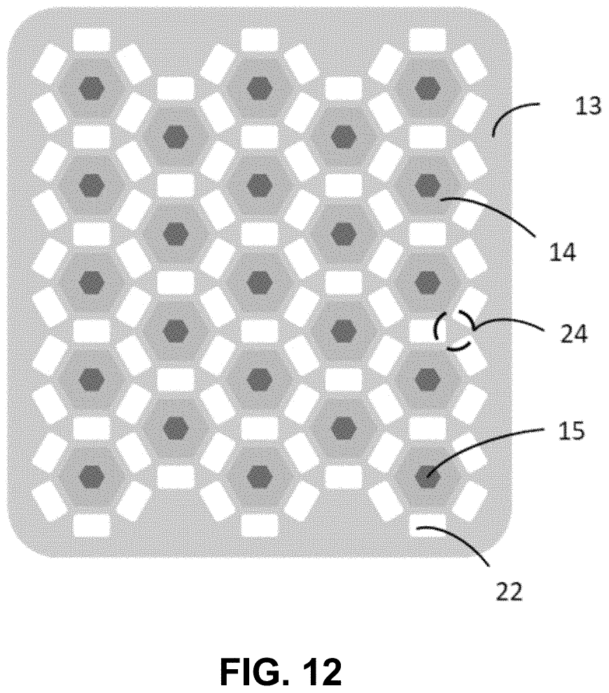

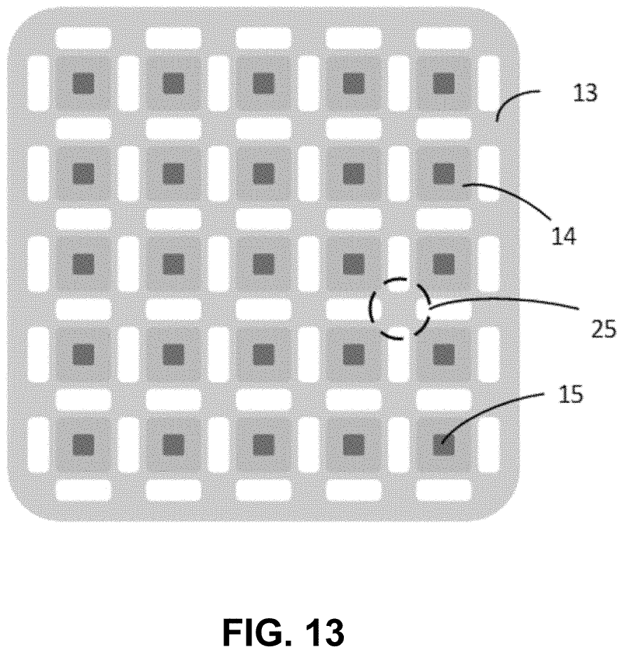

FIGS. 11 to 13 are partial layout design of a planar power MOSFET with enhanced cell design D in different shape (hexagonal, circle and square). By forming the connected well region, the E-field in the gate oxide can be reduced without changing the process flow and cost, and without sacrificing any other performance.

In summary, the different layout designs shown in the present invention can help the MOSFET device achieve a better balance between on-resistance, short-circuit capability and avalanche capability. Also, the reliability of the power MOSFET device can be improved through a reasonable structure design without changing the process flow and cost, and without sacrificing many other properties.

Having described the invention by the description and illustrations above, it should be understood that these are exemplary of the invention and are not to be considered as limiting. Accordingly, the invention is not to be considered as limited by the foregoing description, but includes any equivalent.

What is claimed is:

1. A planar SiC power MOSFET device comprising:
a substrate having a first conductivity type;
an epitaxial layer having the first conductivity type deposited on one side of the substrate; and
a MOS (metal-oxide-semiconductor) structure formed on the epitaxial layer; said MOS structure including:
a plurality of well regions with a second conductivity type which is different from the first conductivity type, and the well region and the epitaxial layer form a PN junction;
a plurality of source regions with highly doped first conductivity type formed in the well regions on the epitaxial layer, and the source region forms another PN junction with the well region;
a plurality of highly doped regions of the second conductivity type formed in the well region on the epitaxial layer;
an insulating gate oxide layer formed on top of the epitaxial layer and spanned adjacent wells and adjacent source regions; and
a gate electrode formed above the gate oxide layer and spanned adjacent wells and source regions,
wherein a JFET (junction-gate filed-effect transistor) region is formed between two adjacent wells; and one or more central implant regions are added with the second conductivity type on a surface of the JFET region to reduce an electric field in the gate oxide.

2. The planar SiC power MOSFET device of claim 1, wherein a source electrode is formed on top of the planar SiC power MOSFET device, and the gate electrode and the source electrode are separated by an insulating dielectric layer.

3. The planar SiC power MOSFET device of claim 1, wherein a drain electrode is formed on the other side of the substrate.

4. The planar SiC power MOSFET device of claim 1, wherein the central implant region can be rectangular, circular, hexagonal, octagonal or any other polygonal shapes.

5. The planar SiC power MOSFET device of claim 1, wherein the central implant regions can be connected with each other, and then connected to the source region.

6. The planar SiC power MOSFET device of claim 1, wherein the central implant regions can connect to the well regions to connect to the source regions.

7. The planar SiC power MOSFET device of claim 1, wherein the JFET regions can be independent from each other, and the well regions between adjacent JFET regions can help reduce the electric field in the gate oxide layer under the forward blocking mode.
